(19) United States
(12) Patent Application Publication
(10) Pub. No.: US 2025/0054544 A1
(43) Pub. Date: Feb. 13, 2025

(54) DATA WRITING OPERATION METHOD AND DEVICE FOR RESISTIVE RANDOM ACCESS MEMORY

(71) Applicant: Xiamen Industrial Technology Research Institute Co., Ltd., Xiamen (CN)

(72) Inventors: Anqiao CHEN, Xiamen (CN); Taiwei CHIU, Taiwan (CN); SZU-CHUN KANG, Taiwan (CN); Hongyao WU, Xiamen (CN); Wuxin LI, Xiamen (CN); Enping CHENG, Xiamen (CN); Xiaoli SU, Xiamen (CN); Yongde ZHANG, Xiamen (CN)

(21) Appl. No.: 18/927,830

(22) Filed: Oct. 25, 2024

(30) Foreign Application Priority Data
Nov. 9, 2023 (CN) 202311489482.7

(51) Int. Cl. G11C 13/00

(52) U.S. Cl. CPC G11C 13/0069; G11C 2013/0078; G11C 2213/79

(57) ABSTRACT

The disclosure discloses a data writing operation method and device of a resistive random access memory, and the method includes: applying a first pulse voltage to the resistive random access memory, and adding one to a corresponding number to obtain a first number; if the current first number is greater than a first set upper limit value and a current second number is smaller than or equal to a second set upper limit value, obtaining a test value; if the test value does not satisfy a preset condition, applying a second pulse voltage to the resistive random access memory, and adding one to the corresponding number to obtain a second number until the test value satisfies the preset condition or the current second number is greater than the second set upper limit value, thereby improving the writing efficiency.

### CROSS-REFERENCE TO RELATED APPLICATIONS

This application claims the benefit of priority from Chinese Patent Application No. 202311489482.7, filed on Nov. 9, 2023. The content of the aforementioned application, including any intervening amendments thereto, is incorporated herein by reference in its entirety.

### TECHNICAL FIELD

The present disclosure relates to the field of semiconductor technology, and in particular, to a data writing operation method of a resistive random access memory and a data writing operation device of a resistive random access memory.

### BACKGROUND

In the related art, as shown in FIG. 1, for a Resistive Random Access Memory (RRAM) array operation for storage applications, typically, when a constant voltage is applied to the word line (WL), a driving signal is applied to the bit line (BL), and the source line (SL) is grounded, the state of the RRAM changes from a high resistance state to a low resistance state, representing a writing operation of 1. Conversely, when a constant voltage is applied to the WL, the BL is grounded, and a driving signal is applied to the SL, the state of the RRAM changes from a low resistance state to a high resistance state, representing a writing operation of 0. The corresponding writing operation is illustrated in FIG. 2, and the means of equal voltage pulse excitation is applied. When the excitation is applied, it is confirmed that the resistance value of the memory cell satisfies the set requirements. If not, additional pulses are applied until the requirements are met or the maximum number of pulses is reached.

However, in the prior art writing operation, due to the IR drop of the actual circuit and the physical structure differences of the memory cells in the memory array (from the manufacturing process), there is inevitably a proportion of the memory cells that have not reached a set resistance value within a limited number of pulses, called a trailing bit. FIG. 3 demonstrates that the memory cell that has not been “properly operated” exhibit a higher probability of degradation (i.e., the written resistance state drifts over time), which can easily lead to errors. Furthermore, as shown in FIG. 4, using the existing writing operation, the time spent on operating the tailing bit is significantly longer than that for normal memory cells, resulting in lower overall efficiency.

### SUMMARY

The present disclosure aims to at least partially address one of the technical problems mentioned above. To this end, one objective of the present disclosure is to propose a data writing operation method for a resistive random access memory (RRAM). This method involves screening out the tailing bit by judging the accumulated number of pulses and further processing the tailing bit by using long pulses and removing current limiting, thereby improving the data retention characteristic while also saving operation time and ultimately enhancing the writing efficiency.

A second objective of the present disclosure is to propose a computer-readable storage medium.

A third objective of the present disclosure is to propose a chip.

A fourth objective of the present disclosure is to propose a computer program product.

A fifth objective of the present disclosure is to provide a data writing operation device of a resistive random access memory.

In order to achieve the above objectives, according an embodiment of the present disclosure in the first aspect, there is provided a data writing operation method of a resistive random access memory, comprising the steps of: applying a first pulse voltage to the resistive random access memory and adding one to a corresponding first applied pulse number to obtain a current first applied pulse number; judging whether the current first applied pulse number is greater than a first set upper limit value; judging whether a current second applied pulse number is greater than a second set upper limit value if the current first applied pulse number is greater than the first set upper limit value; testing the resistance state of a resistive random access memory cell to obtain a corresponding test value if the current second applied pulse number is smaller than or equal to the second set upper limit value; judging whether the test value satisfies a preset condition; and if the test value does not satisfy the preset condition, applying a second pulse voltage to the resistive random access memory, and adding one to the corresponding second applied pulse number, to obtain the current second applied pulse number, until the test value satisfies the preset condition or the current second applied pulse number is greater than the second set upper limit value to complete a data writing operation of the resistive random access memory, wherein a pulse width and a current-limiting value corresponding to the first pulse voltage are smaller than those corresponding to the second pulse voltage.

According to the data writing operation method of the resistive random access memory according to the embodiment of the present disclosure, first, a first pulse voltage is applied to the resistive random access memory and one is added to a corresponding first applied pulse number to obtain a current first applied pulse number; next, whether the current first applied pulse number is greater than a first set upper limit value is judged; whether a current second applied pulse number is greater than a second set upper limit value is judged if the current first applied pulse number is greater than the first set upper limit value; the resistance state of a resistive random access memory cell is tested to obtain a corresponding test value if the current second applied pulse number is smaller than or equal to the second set upper limit value; then, whether the test value satisfies a preset condition is judged; if the test value does not satisfy the preset condition, a second pulse voltage is applied to the resistive random access memory, and one is added to the corresponding second applied pulse number, to obtain the current second applied pulse number, until the test value satisfies the preset condition or the current second applied pulse number is greater than the second set upper limit value to complete a data writing operation of the resistive random access memory, wherein a pulse width and a current-limiting value corresponding to the first pulse voltage are smaller than those corresponding to the second pulse voltage. Thus, the tailing bit is screened by judging the accumulated number of pulses, and further processed by using long pulses and releasing the current-limiting value, thereby improving the data retention characteristic while also saving operation time and ultimately enhancing the writing efficiency.

In addition, the data writing operation method of the resistive random access memory proposed according to the above embodiments of the present disclosure may further have additional technical features as follows:

Optionally, if the current first applied pulse number is smaller than or equal to the first set upper limit value, testing the resistance state of the resistive random access memory cell to obtain a corresponding test value, and judging whether the test value satisfies a preset condition, if the test value satisfies the preset condition, completing a data writing operation of the resistive random access memory, and if the test value does not satisfy the preset condition, continuing to apply the first pulse voltage to the resistive random access memory until the test value satisfies the preset condition.

Optionally, if the current second applied pulse number is greater than the second set upper limit value, completing the data writing operation of the resistive random access memory, and judging that writing is failed.

Optionally, if the test value satisfies the preset condition, completing the data writing operation of the resistive random access memory is completed, and judging that writing is successful.

Optionally, judging whether the test value satisfies the preset condition includes: judging whether the test value is greater than or equal to a first set resistance value and smaller than or equal to a second set resistance value, wherein the first set resistance value is smaller than the second set resistance value.

Optionally, initial values of the first applied pulse number and the second applied pulse number are each set to zero.

In order to achieve the above objective, an embodiment of the present disclosure in the second aspect provides a computer-readable storage medium having stored thereon a data writing operation program of a resistive random access memory which, when executed by a processor, implements the data writing operation method of the resistive random access memory as described above.

The computer-readable storage medium according to an embodiment of the present disclosure, by storing the data writing operation program of the resistive random access memory, enables the processor to implement the data writing operation method of the resistive random access memory as described above when executing the data writing operation program of the resistive random access memory, the operation time is saved while improving the data retention characteristic, thereby improving the writing efficiency.

In order to achieve the above objective, an embodiment of the present disclosure in the third aspect provides a chip comprising a memory, a processor, and a data writing operation program of a resistive random access memory stored on the memory and operable on the processor, the processor, when executing the data writing operation program of the resistive random access memory, implementing the data writing operation method of the resistive random access memory as described above.

By the chip according to an embodiment of the disclosure, the data writing operation program of the resistive random access memory operable on the processor is stored by the memory so that the processor implements the data writing operation method of the resistive random access memory as described above when executing the program, the operation time is saved while improving the data retention characteristic, thereby improving the writing efficiency.

In order to achieve the above objective, an embodiment of the present disclosure in the fourth aspect provides a computer program product comprising a computer program which, when executed by a processor, implements the data writing operation method of the resistive random access memory as described above.

The computer program product according to an embodiment of the present disclosure, when executed by a processor, implements the data writing operation method of the resistive random access memory as described above, the operation time is saved while improving the data retention characteristic, thereby improving the writing efficiency.

In order to achieve the above objective, according to an embodiment of the present disclosure in the fifth aspect, there is provided a data writing operation device of a resistive random access memory, comprising: a first excitation module, configured to apply a first pulse voltage to the resistive random access memory and add one to a corresponding first applied pulse number to obtain a current first applied pulse number; a first judging module, configured to judge whether the current first applied pulse number is greater than a first set upper limit value; a second judging module, configured to judge whether a current second applied pulse number is greater than a second set upper limit value if the current first applied pulse number is greater than the first set upper limit value; a test module, configured to test the resistance state of a resistive random access memory cell to obtain a corresponding test value if the current second applied pulse number is smaller than or equal to the second set upper limit value; a third judging module, configured to judge whether the test value satisfies a preset condition; and a second excitation module, configured to, if the test value does not satisfy the preset condition, apply a second pulse voltage to the resistive random access memory, and add one to the corresponding second applied pulse number, to obtain the current second applied pulse number, until the test value satisfies the preset condition or the current second applied pulse number is greater than the second set upper limit value to complete a data writing operation of the resistive random access memory, wherein a pulse width and a current-limiting value corresponding to the first pulse voltage are smaller than those corresponding to the second pulse voltage.

In accordance with an embodiment of the present disclosure, a data writing operation apparatus of a resistive random access memory screens out a trailing bit by judging the number of accumulated pulses, and further processes the trailing bit using longer pulses and releasing the current-limiting value, thereby saving operation time while improving the data retention characteristic, and further improving the writing efficiency.

### BRIEF DESCRIPTION OF THE DRAWINGS

FIG. 1 is a schematic diagram illustrating a circuit structure of a memory array cell in the prior art;

FIG. 2 is a flowchart illustrating a data writing operation method of a resistive random access memory in the prior art;

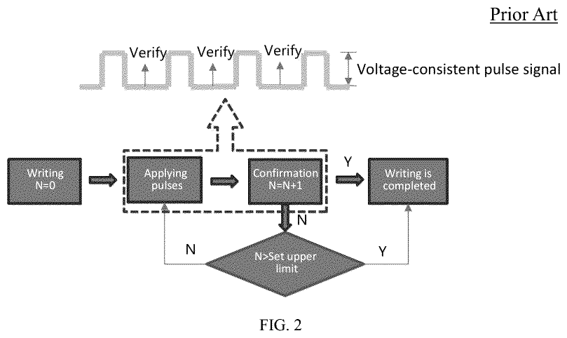

FIG. 3 is a schematic diagram illustrating a probability distribution of degradation occurring in a memory cell that have not been operated properly in the prior art;

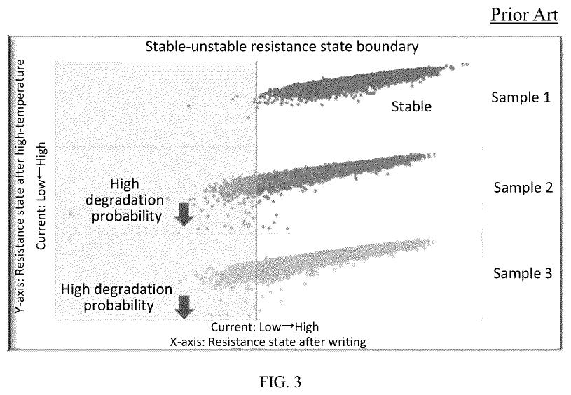

FIG. 4 is a schematic diagram illustrating the statistics of the number of pulses required to write 1 to each memory cell in an array;

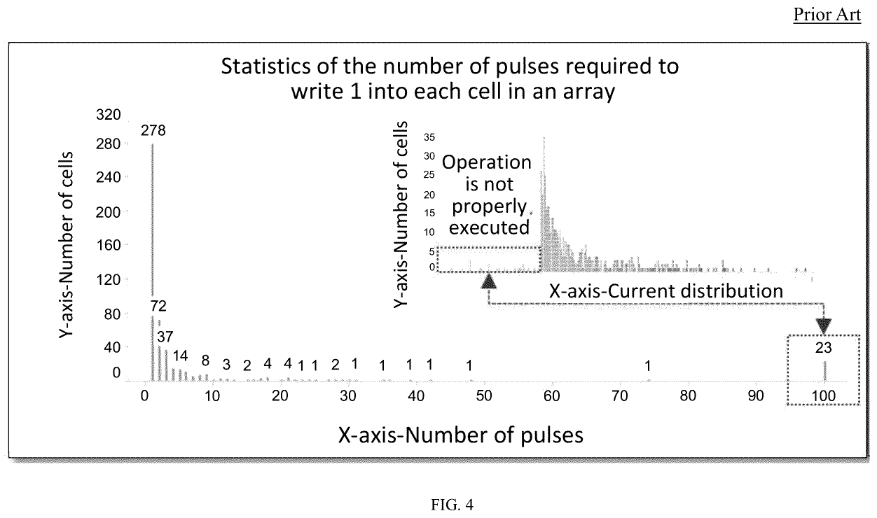

FIG. 5 is a flowchart illustrating a data writing operation of a resistive random access memory according to embodiments of the present disclosure;

FIG. 6 is a flowchart illustrating a data writing operation of a resistive random access memory according to one embodiment of the present disclosure;

FIG. 7 is a schematic diagram illustrating the effect of a long pulse width on a data retention characteristic according to an embodiment of the present disclosure; and

FIG. 8 is a schematic diagram illustrating the effect of a current-limiting value on the data retention characteristic according to an embodiment of the present disclosure.

### DETAILED DESCRIPTION

Embodiments of the present disclosure are described in detail below, examples of which are shown in the accompanying drawings, wherein identical or similar reference numerals denote identical or similar elements or elements having identical or similar functions throughout. The embodiments described below with reference to the accompanying drawings are exemplary and are intended to be used to explain the present disclosure, and are not to be construed as limiting the present disclosure.

In order to better understand the above-described technical solutions, exemplary embodiments of the present disclosure will be described in more detail below with reference to the accompanying drawings. Although exemplary embodiments of the disclosure are shown in the drawings, it should be understood that the disclosure may be implemented in various forms and should not be limited by the embodiments set forth herein. Rather, these embodiments are provided in order to enable a more thorough understanding of the disclosure and to fully convey the scope of the disclosure to those skilled in the art.

For a better understanding of the above technical solutions, the above technical solutions will be described in detail below in conjunction with the description drawings and the specific embodiments.

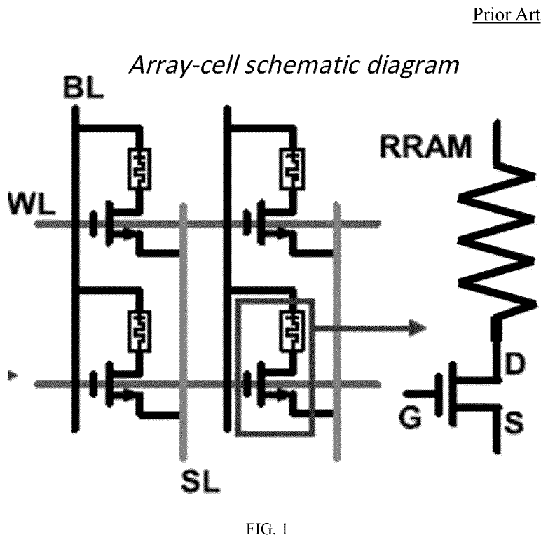

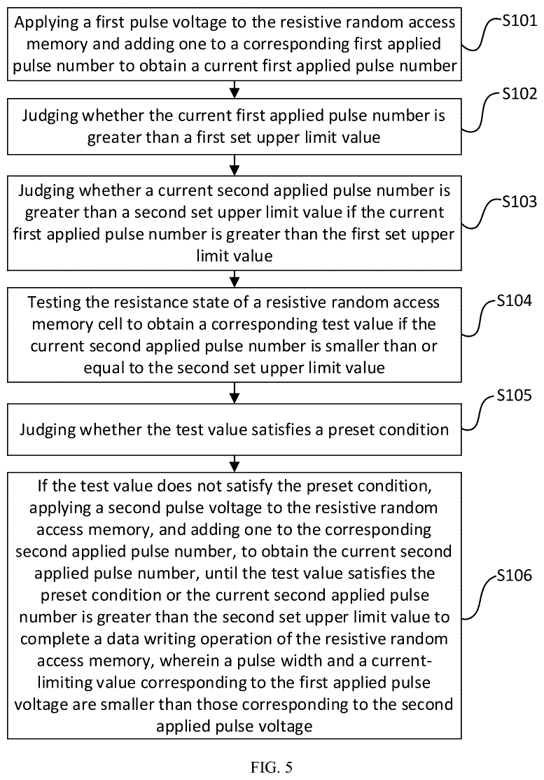

Please refer to FIG. 5, which is a flowchart illustrating a data writing operation of a resistive random access memory according to embodiments of the present disclosure, the data writing operation method of the resistive random access memory according to FIG. 1 includes the following steps:

S101, a first pulse voltage is applied to the resistive random access memory and one is added to a corresponding first applied pulse number to obtain a current first applied pulse number.

That is, during the writing operation, the resistive random access memory is first excited using a normally-sized first pulse voltage (equal voltage pulse), and after the excitation, the first applied pulse number is added by one so as to count the current pulse excitation number.

It should be noted that the first applied pulse number may be defined as N, and its initial value is set to zero.

S102, whether the current first applied pulse number is greater than a first set upper limit value is judged.

That is, the first set upper limit value N_{jud} is defined as necessary before the writing operation is performed so that the relationship between the first applied pulse number N and the first set upper limit value N_{jud} is counted.

S103, whether a current second applied pulse number is greater than a second set upper limit value is judged if the current first applied pulse number is greater than the first set upper limit value.

Wherein, the second applied pulse number may be defined as M, and its initial value is set to zero.

That is, when the relationship between the first applied pulse number N and the first set upper limit value N_{jud} is such that the current first applied pulse number N is greater than the first set upper limit value N_{jud}, a trailing bit is determined, and further processing of the screened trailing bit is required since more trailing bits again affect the reliability of the array.

It should be noted that a second set upper limit value M_{jud} is defined as necessary before the writing operation is performed, so that the relationship between the second applied pulse number M and the second set upper limit value M_{jud} is counted, N_{jud} and M_{jud} are upper limits of the pulse number set for saving time for the large-scale array operation, and exceeding the set value of M_{jud} indicates that the initialization has failed.

As one example, the second set upper limit value M_{jud} is greater than the first set upper limit value N_{jud}, wherein the first set upper limit value N_{jud} may be set to be 100, and the second set upper limit value M_{jud} may be set to be 200.

As one embodiment, if the current first applied pulse number is smaller than or equal to a first set upper limit value, the resistance state of the resistive random access memory cell is tested to obtain a corresponding test value, and whether the test value satisfies a preset condition is judged, if the test value satisfies the preset condition, a data writing operation of the resistive random access memory is completed, if the test value does not satisfy the preset condition, the first pulse voltage is continuously applied to the resistive random access memory until the test value satisfies the preset condition.

That is, a relationship between the first applied pulse number N and the first set upper limit value N_{jud} is that the current first applied pulse number N is smaller than or equal to the first set upper limit value N_{jud}, then it is stated that the number of the applied pulses has not reached the upper limit of the trailing bit so it needs to further judge whether the test value satisfies the preset condition, if yes, the operation is completed and it is judged that the writing is successful, if not, the next round of excitation is performed with the first pulse voltage until the test value satisfies the preset condition; if the current first applied pulse number N is greater than the first set upper limit value N_{jud} without satisfying the preset condition, the trailing bit processing flow is entered.

S104, the resistance state of a resistive random access memory cell is tested to obtain a corresponding test value if the current second applied pulse number is smaller than or equal to the second set upper limit value.

As one embodiment, if the current second applied pulse number is greater than the second set upper limit value, the data writing operation of the resistive random access memory is completed, and it is judged that the writing is failed.

It should be noted that in order to save time, the second set upper limit value M_{jud} is set, exceeding the M_{jud} setting indicates that the initialization has failed. However, for the tailing bit that has undergone a longer pulse width excitation treatment when the second applied pulse number M has not exceeded the second set upper limit M_{jud}, even if it does not reach the stability threshold within the set upper limit (M_{jud}), it will still exhibit a better data retention characteristic.

S105, whether the test value satisfies a preset condition is judged.

S106, if the test value does not satisfy the preset condition, a second pulse voltage is applied to the resistive random access memory, and one is added to the corresponding second applied pulse number to obtain the current second applied pulse number, until the test value satisfies the preset condition or the current second applied pulse number is greater than the second set upper limit value to complete a data writing operation of the resistive random access memory, wherein a pulse width and a current-limiting value corresponding to the first pulse voltage are smaller than those corresponding to the second pulse voltage.

As an example, the pulse width corresponding to the second pulse voltage may be set to 10 times the pulse width corresponding to the first pulse voltage, and the current-limiting value corresponding to the second pulse voltage may be set to 10%-20% of the current-limiting value corresponding to the first pulse voltage, which is not particularly limited in the present disclosure.

It should be noted that by adding a process to handle the tailing bit, specifically by identifying the tailing bit based on the number of pulses exceeding the set upper limit N_{jud}, and subsequently applying additional pulses with longer pulse widths and releasing the current-limiting value to optimize the data retention characteristic, this approach enables the excitation of longer pulse widths and higher currents to push the tailing bit beyond the stability threshold. Furthermore, the tailing bit that has undergone excitation with longer pulse widths, even if it does not reach the stability threshold within the set upper limit M_{jud}, will exhibit the better data retention characteristic. By introducing this mechanism, the upper limit on the number of pulses in the conventional phase can be reduced, and by adjusting the appropriate ratio of N_{jud}/M_{jud} and pulse widths, the writing efficiency can be significantly increased.

As one embodiment, if the test value satisfies a preset condition, the data writing operation of the resistive random access memory is completed, and it is judged that the writing is successful.

As a specific embodiment, the step that whether the test value satisfies the preset condition is judged includes: whether the test value is greater than or equal to a first set resistance value and smaller than or equal to a second set resistance value is judged, wherein the first set resistance value is smaller than the second set resistance value.

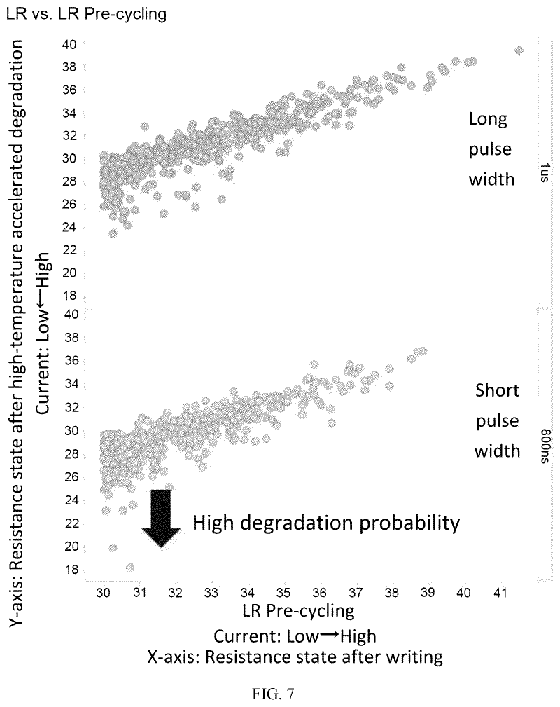

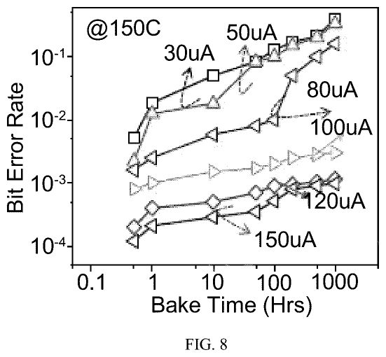

Additionally, as shown in FIG. 7, the relationship of the pulse width to the data retention characteristic is positively correlated, that is, the pulse width is increased so that the data retention characteristic is increased. Therefore, by screening the tailing bit based on the pulse number and applying special treatment with longer pulses and released current-limiting value, it not only facilitates pushing the tailing bit beyond the stability threshold but also provides an additional stabilizing effect on resistance states even if the tailing bit does not reach the stability threshold within the specified number of pulses. As depicted in FIG. 8, there is also a positive correlation between the current-limiting value and the data retention characteristic, indicating that as the current-limiting value increases, the data retention characteristic improves accordingly. By utilizing this special treatment mechanism for the tailing bit, we can avoid the issues of existing technologies that consume longer times without achieving satisfactory results. By adjusting the parameters such as M_{jud}, N_{jud}, pulse width, and current-limiting value, significant savings in operation time can be achieved, leading to a substantial increase in writing efficiency.

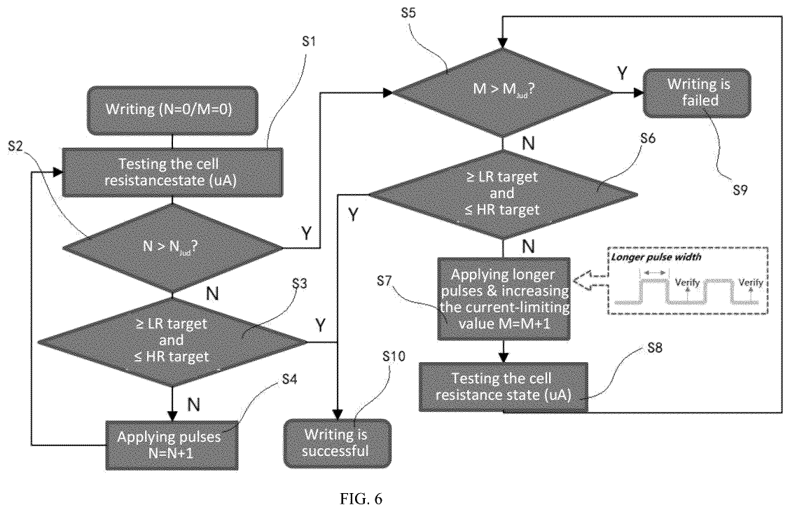

In addition, FIG. 6 is a flowchart illustrating a data writing operation of a resistive random access memory according to one embodiment of the present disclosure, as shown in FIG. 6, the data writing operation method of the resistive random access memory includes the following steps:
S1, the resistance state of the memory cell is tested to obtain a test value.
S2, whether the first applied pulse number is greater than a first set upper limit value is judged; if yes, step S5 is entered, if not, step S3 is executed.
S3, whether the test value is greater than or equal to a first set resistance value and smaller than or equal to a second set resistance value is judged; if yes, step S10 is entered; if not, step S4 is executed.
S4, a first pulse voltage is applied, and a first applied pulse number is added by one; then step S1 is entered.
S5, whether the current second applied pulse number is greater than a second set upper limit value is judged; if yes, step S9 is entered; if not, the step S6 is executed.
S6, whether the test value is greater than or equal to a first set resistance value and smaller than or equal to a second set resistance value is judged; if yes, step S10 is entered; if not, step S7 is executed.
S7, a second pulse voltage is applied and a second applied pulse number is added by one, wherein a pulse width and a current-limiting value corresponding to the first pulse voltage are smaller than a pulse width and a current-limiting value corresponding to the second pulse voltage; thereafter step S8 is entered.
S8, the resistance state of the memory cell is tested to obtain a test value; thereafter step S5 is entered.
S9, the writing is failed.
S10, the writing is successful.

In summary, according to the data writing operation method of the resistive random access memory according to the embodiment of the present disclosure, first, a first pulse voltage is applied to the resistive random access memory, and a corresponding first applied pulse number is added by one to obtain a current first applied pulse number; next, whether the current first applied pulse number is greater than a first set upper limit value is judged; if the current first applied pulse number is greater than the first set upper limit value, whether the current second applied pulse number is greater than a second set upper limit value is judged; the resistance state of the resistive random access memory cell is tested to obtain a corresponding test value if the current second applied pulse number is smaller than or equal to a second set upper limit value; then, whether the test value satisfies a preset condition is judged; if the test value does not satisfy the preset condition, a second pulse voltage is applied to the resistive random access memory, and the corresponding second applied pulse number is added by one to obtain a current second applied pulse number until the test value satisfies the preset condition or the current second applied pulse number is greater than a second set upper limit value to complete the data writing operation of the resistive random access memory, wherein the pulse width and the current-limiting value corresponding to the first pulse voltage are smaller than the pulse width and the current-limiting value corresponding to the second pulse voltage; thus, the tailing bit is screened by judging the accumulated number of pulses, and further processed by using longer pulses and releasing the current-limiting value, thereby saving operation time while improving the data retention characteristic, and thus improving writing efficiency.

In order to realize the above-described embodiments, an embodiment of the present disclosure in the second aspect proposes a computer-readable storage medium having stored thereon a data writing operation program of a resistive random access memory which, when executed by a processor, implements the data writing operation method of the resistive random access memory as described above.

According to the embodiment of the present disclosure, the computer-readable storage medium stores a data writing operation program for a resistive random access memory, enabling the processor to implement the aforementioned data writing operation method of the resistive random access memory when executing the data writing operation program for the resistive random access memory. This, in turn, enhances the data retention characteristic while reducing operation time, thereby improving writing efficiency.

To implement the above embodiments, according to an embodiment of the present disclosure in the third aspect, there is provided a chip comprising a memory, a processor, and a data writing operation program of a resistive random access memory stored on the memory and operable on the processor, the program, when executed by the processor, implements the data writing operation method of the resistive random access memory.

By the chip according to an embodiment of the disclosure, the data writing operation program of the resistive random access memory operable on the processor is stored by the memory so that the processor implements the data writing operation method of the resistive random access memory as described above when executing the program, the operation time is saved while improving the data retention characteristic, thereby improving the writing efficiency.

In order to achieve the above embodiment, an embodiment of the present disclosure in the fourth aspect provides a computer program product comprising a computer program which, when executed by a processor, implements the data writing operation method of the resistive random access memory as described above.

The computer program product according to an embodiment of the present disclosure, when executed by a processor, implements the data writing operation method of the resistive random access memory as described above, the operation time is saved while improving the data retention characteristic, thereby improving the writing efficiency.

In order to realize the above embodiment, the present embodiment further proposes a data writing operation device of a resistive random access memory, which includes: a first excitation module, a first judging module, a second judging module, a testing module, a third judging module and a second excitation module.

Wherein a first excitation module is configured to apply a first pulse voltage to the resistive random access memory and add one to a corresponding first applied pulse number to obtain a current first applied pulse number; a first judging module is configured to judge whether the current first applied pulse number is greater than a first set upper limit value; a second judging module is configured to judge whether a current second applied pulse number is greater than a second set upper limit value if the current first applied pulse number is greater than the first set upper limit value; a test module is configured to test the resistance state of a resistive random access memory cell to obtain a corresponding test value if the current second applied pulse number is smaller than or equal to the second set upper limit value; a third judging module is configured to judge whether the test value satisfies a preset condition; and a second excitation module, is configured to, if the test value does not satisfy the preset condition, apply a second pulse voltage to the resistive random access memory, and add one to the corresponding second applied pulse number, to obtain the current second applied pulse number, until the test value satisfies the preset condition or the current second applied pulse number is greater than the second set upper limit value to complete a data writing operation of the resistive random access memory, wherein a pulse width and a current-limiting value corresponding to the first pulse voltage are smaller than those corresponding to the second pulse voltage.

It should be noted that the above description of the data writing operation method for the resistive random access memory is equally applicable to the data writing operation device for the resistive random access memory, and will not be described in detail herein.

In view of the above, according to an embodiment of the present disclosure, the data writing operation device for the resistive random access memory screens out a trailing bit by judging the number of accumulated pulses, and further processes the trailing bit using longer pulses and releasing the current-limiting value, thereby saving operation time while improving the data retention characteristic, and further improving the writing efficiency.

It will be appreciated by those skilled in the art that the embodiments of the present disclosure may be provided as methods, systems, or computer program products. Accordingly, the present disclosure may take the form of an entirely hardware embodiment, an entirely software embodiment, or an embodiment combining software and hardware aspects. Furthermore, the present disclosure may take the form of a computer program product embodied on one or more computer-usable storage media (including, but not limited to, magnetic disk storage, CD-ROM, optical memory, etc.) containing computer-usable program code therein.

The present disclosure is described with reference to flowcharts and/or block diagrams of methods, apparatus (systems), and computer program products according to embodiments of the disclosure. It should be understood that each flow and/or block in the flowchart and/or block diagrams, and combinations of the flows and/or blocks in the flowcharts and/or block diagrams, may be implemented by computer program instructions. These computer program instructions may be provided to a processor of a general-purpose computer, a special purpose computer, an embedded processor, or other programmable data processing apparatus to produce a machine such that the instructions executed by the processor of the computer or other programmable data processing apparatus produce means for implementing the functions specified in one flow or more flows of the flowchart diagrams and/or one block or more blocks of the block diagrams.

These computer program instructions may also be stored in a computer-readable memory capable of directing a computer or other programmable data processing apparatus to operate in a particular manner such that the instructions stored in the computer-readable memory produce an article of manufacture comprising instruction means for implementing the functions specified in a flow or flows of the flowcharts and/or a block or blocks of the block diagrams.

These computer program instructions may also be loaded onto a computer or other programmable data processing apparatus such that a series of operational steps are performed on the computer or other programmable apparatus to produce a computer-implemented process, such that the instructions executed on the computer or other programmable apparatus provide steps for implementing the functions specified in one flow or more flows of the flowcharts and/or one block or more blocks of the block diagrams.

It should be noted that in the claims, any reference signs placed between parentheses shall not be constructed as limiting the claim. The word “comprising” does not exclude the presence of elements or steps not listed in a claim. The word “a” or “an” preceding an element does not exclude the presence of a plurality of such elements. The disclosure may be implemented by means of hardware comprising several distinct elements, and by means of a suitably programmed computer. In the unit claim enumerating several means, several of these means may be embodied by one and the same item of hardware. The use of the words first, second, and third, etc. does not indicate any order. These words can be interpreted as names.

While preferred embodiments of the present disclosure have been described, those skilled in the art, once the basic inventive concept has been learned, can make additional variations and modifications to these embodiments. Therefore, it is intended that the appended claims be interpreted as including the preferred embodiments and all changes and modifications that fall within the scope of the disclosure.

It will be apparent that those skilled in the art can make various modifications and modifications to the present disclosure without departing from the spirit and scope of the present disclosure. Thus, the present disclosure is intended to embrace such modifications and variations if they fall within the scope of the claims of the present disclosure and their equivalents.

In the description of the present disclosure, it is to be understood that the terms “first” and “second” are used for descriptive purposes only and cannot be understood to indicate or imply relative importance or to implicitly indicate the number of technical features indicated. Thus, features defined as “first” and “second” may explicitly or implicitly include one or more of such features. In the description of the present disclosure, “plurality” means two or more, unless expressly and specifically defined otherwise.

As used herein, unless expressly stated and limited otherwise, the terms “mounted”, “connected”, “connection”, “fixed” and the like are to be construed broadly, for example, “connection” may be fixed connection or detachable connection or integrated connection, may be mechanical connection or electrical connection, may be direct connection or indirect connection through an intermediate medium, and may be internal connection of two elements or the interaction of two elements. For those of ordinary skilled in the art, the specific meanings of the above terms in the present application may be understood according to specific situations.

In this application, unless expressly stated and defined otherwise, a first feature being “above” or “below” a second feature can include that the first and second features are in direct contact or can include that the first and second features are not in direct contact but are in indirect contact through an intermediate medium. Also, a first feature being “above” and “on” a second feature includes the first feature being directly above and obliquely above the second feature, or simply indicates that the first feature is at a higher level than the second feature. A first feature being “below” and “beneath” a second feature includes the first feature being directly below and obliquely below the second feature, or simply indicating that the first feature is at a lower level than the second feature.

In the description of the present specification, a description with reference to the terms “one embodiment,” “some embodiments,” “examples,” “specific examples,” or “some examples” or the like means that a specific feature, structure, material, or characteristic described in connection with the embodiment or example is included in at least one embodiment or example of the present disclosure. In this specification, schematic expressions of the above terms should not be understood as necessarily directed to the same embodiment or example. Furthermore, the specific features, structures, materials, or features described may be combined in any one or more embodiments or examples in a suitable manner. Furthermore, those skilled in the art can combine and combine different embodiments or examples described in this specification and features of different embodiments or examples without contradicting each other.

Although embodiments of the present disclosure have been shown and described above, it should be understood that the above embodiments are exemplary and should not be construed as limitations of the present disclosure, and those skilled in the art can make changes, modifications, substitutions and variations to the above embodiments within the scope of the present disclosure.

What is claimed is:

1. A data writing operation method of a resistive random access memory (RRAM), comprising:
applying a first pulse voltage to the resistive random access memory and adding one to a corresponding first applied pulse number to obtain a current first applied pulse number;
judging whether the current first applied pulse number is greater than a first set upper limit value;
judging whether a current second applied pulse number is greater than a second set upper limit value if the current first applied pulse number is greater than the first set upper limit value;
testing the resistance state of a resistive random access memory cell to obtain a corresponding test value if the current second applied pulse number is smaller than or equal to the second set upper limit value;
judging whether the test value satisfies a preset condition; and
if the test value does not satisfy the preset condition, applying a second pulse voltage to the resistive random access memory, and adding one to the corresponding second applied pulse number, to obtain the current second applied pulse number, until the test value satisfies the preset condition or the current second applied pulse number is greater than the second set upper limit value to complete a data writing operation of the resistive random access memory, wherein a pulse width and a current-limiting value corresponding to the first pulse voltage are smaller than those corresponding to the second pulse voltage.

2. The data writing operation method of a resistive random access memory according to claim 1, wherein, if the current first applied pulse number is smaller than or equal to the first set upper limit value, testing the resistance state of the resistive random access memory cell to obtain a corresponding test value, and judging whether the test value satisfies a preset condition, if the test value satisfies the preset condition, completing a data writing operation of the resistive random access memory, and if the test value does not satisfy the preset condition, continuing to apply the first pulse voltage to the resistive random access memory until the test value satisfies the preset condition.

3. The data writing operation method of a resistive random access memory according to claim 2, wherein, if the current second applied pulse number is greater than the second set upper limit value, completing the data writing operation of the resistive random access memory, and judging that writing is failed.

4. The data writing operation method of a resistive random access memory according to claim 3, wherein, if the test value satisfies the preset condition, completing the data writing operation of the resistive random access memory is completed, and judging that writing is successful.

5. The data writing operation method of a resistive random access memory according to claim 4, wherein judging whether the test value satisfies the preset condition comprises:
judging whether the test value is greater than or equal to a first set resistance value and smaller than or equal to a second set resistance value, wherein the first set resistance value is smaller than the second set resistance value.

6. The data writing operation method of a resistive random access memory according to claim 1, wherein initial values of the first applied pulse number and the second applied pulse number are each set to zero.

7. The data writing operation method of a resistive random access memory according to claim 2, wherein initial values of the first applied pulse number and the second applied pulse number are each set to zero.

8. The data writing operation method of a resistive random access memory according to claim 3, wherein initial values of the first applied pulse number and the second applied pulse number are each set to zero.

9. The data writing operation method of a resistive random access memory according to claim 4, wherein initial values of the first applied pulse number and the second applied pulse number are each set to zero.

10. The data writing operation method of a resistive random access memory according to claim 5, wherein initial values of the first applied pulse number and the second applied pulse number are each set to zero.

11. A computer-readable storage medium having stored thereon a data writing operation program of a resistive random access memory which, when executed by a processor, implements the data writing operation method of the resistive random access memory according to claim 1.

12. A computer-readable storage medium having stored thereon a data writing operation program of a resistive random access memory which, when executed by a processor, implements the data writing operation method of the resistive random access memory according to claim 2.

13. A computer-readable storage medium having stored thereon a data writing operation program of a resistive random access memory which, when executed by a processor, implements the data writing operation method of the resistive random access memory according to claim 3.

14. A computer-readable storage medium having stored thereon a data writing operation program of a resistive random access memory which, when executed by a processor, implements the data writing operation method of the resistive random access memory according to claim 4.

15. A computer-readable storage medium having stored thereon a data writing operation program of a resistive random access memory which, when executed by a processor, implements the data writing operation method of the resistive random access memory according to claim 5.

16. A computer-readable storage medium having stored thereon a data writing operation program of a resistive random access memory which, when executed by a processor, implements the data writing operation method of the resistive random access memory according to claim 6.

17. A computer-readable storage medium having stored thereon a data writing operation program of a resistive random access memory which, when executed by a processor, implements the data writing operation method of the resistive random access memory according to claim 7.

18. A computer-readable storage medium having stored thereon a data writing operation program of a resistive random access memory which, when executed by a processor, implements the data writing operation method of the resistive random access memory according to claim 8.

19. A computer-readable storage medium having stored thereon a data writing operation program of a resistive random access memory which, when executed by a processor, implements the data writing operation method of the resistive random access memory according to claim 9.

20. A computer-readable storage medium having stored thereon a data writing operation program of a resistive random access memory which, when executed by a processor, implements the data writing operation method of the resistive random access memory according to claim 10.

21. A chip, comprising a memory, a processor, and a data writing operation program of a resistive random access memory stored on the memory and operable on the processor, the processor, when executing the data writing operation program of the resistive random access memory, implementing the data writing operation method of the resistive random access memory according to claim 1.

22. A chip, comprising a memory, a processor, and a data writing operation program of a resistive random access memory stored on the memory and operable on the processor, the processor, when executing the data writing operation program of the resistive random access memory, implementing the data writing operation method of the resistive random access memory according to claim 2.

23. A chip, comprising a memory, a processor, and a data writing operation program of a resistive random access memory stored on the memory and operable on the processor, the processor, when executing the data writing operation program of the resistive random access memory, implementing the data writing operation method of the resistive random access memory according to claim 3.

24. A chip, comprising a memory, a processor, and a data writing operation program of a resistive random access memory stored on the memory and operable on the processor, the processor, when executing the data writing operation program of the resistive random access memory, implementing the data writing operation method of the resistive random access memory according to claim 4.

25. A chip, comprising a memory, a processor, and a data writing operation program of a resistive random access memory stored on the memory and operable on the processor, the processor, when executing the data writing operation program of method of the resistive random access memory according to claim 5.

26. A chip, comprising a memory, a processor, and a data writing operation program of a resistive random access memory stored on the memory and operable on the processor, the processor, when executing the data writing operation program of the resistive random access memory, implementing the data writing operation method of the resistive random access memory according to claim 6.

27. A chip, comprising a memory, a processor, and a data writing operation program of a resistive random access memory stored on the memory and operable on the processor, the processor, when executing the data writing operation program of the resistive random access memory, implementing the data writing operation method of the resistive random access memory according to claim 7.

28. A chip, comprising a memory, a processor, and a data writing operation program of a resistive random access memory stored on the memory and operable on the processor, the processor, when executing the data writing operation program of the resistive random access memory, implementing the data writing operation method of the resistive random access memory according to claim 8.

29. A chip, comprising a memory, a processor, and a data writing operation program of a resistive random access memory stored on the memory and operable on the processor, the processor, when executing the data writing operation program of the resistive random access memory, implementing the data writing operation method of the resistive random access memory according to claim 9.

30. A chip, comprising a memory, a processor, and a data writing operation program of a resistive random access memory stored on the memory and operable on the processor, the processor, when executing the data writing operation program of method of the resistive random access memory according to claim 10.

31. A computer program product comprising a computer program which, when executed by a processor, implements a data writing operation method of a resistive random access memory according to claim 1.

32. A computer program product comprising a computer program which, when executed by a processor, implements a data writing operation method of a resistive random access memory according to claim 2.

33. A computer program product comprising a computer program which, when executed by a processor, implements a data writing operation method of a resistive random access memory according to claim 3.

34. A computer program product comprising a computer program which, when executed by a processor, implements a data writing operation method of a resistive random access memory according to claim 4.

35. A computer program product comprising a computer program which, when executed by a processor, implements a data writing operation method of a resistive random access memory according to claim 5.

36. A computer program product comprising a computer program which, when executed by a processor, implements a data writing operation method of a resistive random access memory according to claim 6.

37. A computer program product comprising a computer program which, when executed by a processor, implements a data writing operation method of a resistive random access memory according to claim 7.

38. A computer program product comprising a computer program which, when executed by a processor, implements a data writing operation method of a resistive random access memory according to claim 8.

39. A computer program product comprising a computer program which, when executed by a processor, implements a data writing operation method of a resistive random access memory according to claim 9.

40. A computer program product comprising a computer program which, when executed by a processor, implements a data writing operation method of a resistive random access memory according to claim 10.

41. A data writing operation device of a resistive random access memory, comprising:
a first excitation module, configured to apply a first pulse voltage to the resistive random access memory and add one to a corresponding first applied pulse number to obtain a current first applied pulse number;
a first judging module, configured to judge whether the current first applied pulse number is greater than a first set upper limit value;
a second judging module, configured to judge whether a current second applied pulse number is greater than a second set upper limit value if the current first applied pulse number is greater than the first set upper limit value;
a test module, configured to test the resistance state of a resistive random access memory cell to obtain a corresponding test value if the current second applied pulse number is smaller than or equal to the second set upper limit value;
a third judging module, configured to judge whether the test value satisfies a preset condition; and
a second excitation module, configured to, if the test value does not satisfy the preset condition, apply a second pulse voltage to the resistive random access memory, and add one to the corresponding second applied pulse number, to obtain the current second applied pulse number, until the test value satisfies the preset condition or the current second applied pulse number is greater than the second set upper limit value to complete a data writing operation of the resistive random access memory, wherein a pulse width and a current-limiting value corresponding to the first pulse voltage are smaller than those corresponding to the second pulse voltage.
